(19) United States
(12) Patent Application Publication
(10) Pub. No.: US 2025/0133720 A1
(43) Pub. Date: Apr. 24, 2025

(54) MEMORY DEVICE HAVING HEXAGONAL MEMORY CELLS

(71) Applicant: Micron Technology, Inc., Boise, ID (US)

(72) Inventors: Fatma Arzum Simsek-Ege, Boise, ID (US); Efe Sinan Ege, Boise, ID (US)

(21) Appl. No.: 18/777,396

(22) Filed: Jul. 18, 2024

Related U.S. Application Data
(60) Provisional application No. 63/544,706, filed on Oct. 18, 2023.

(51) Int. Cl. H10B 12/00; G11C 11/4091; H01L 29/06; H01L 29/423; H01L 29/66; H01L 29/775; H01L 29/786

(52) U.S. Cl. CPC H10B 12/315; G11C 11/4091; H10B 12/0335; H10B 12/05; H10B 12/482; H10B 12/488; H10B 12/50; H10D 30/014; H10D 30/43; H10D 30/6735; H10D 30/6757; H10D 62/121

(57) ABSTRACT

A variety of applications can include a memory device having an array of memory cells arranged as hexagonal cells, with each of the memory cells having a gate-all-around (GAA) transistor coupled to a capacitor. An access line can be coupled to gates of a first set of multiple GAA transistors of the memory cells. A digit line can be coupled to a second set of multiple GAA transistors of the memory cells, where the digit line is separated from an adjacent digit line by an airgap. Additional devices and methods are disclosed.

### PRIORITY APPLICATION

This application claims the benefit of priority to U.S. Provisional Application Ser. No. 63/544,706, filed Oct. 18, 2023, which is incorporated herein by reference in its entirety.

### FIELD OF THE DISCLOSURE

Embodiments of the disclosure relate generally to integrated circuits and, more specifically, to memory devices and formation thereof.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, memory devices in an IC for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a representation of an example array of memory cells arranged as hexagonal memory cells, in accordance with various embodiments.

FIG. 2 illustrates an example structure that can be arranged as a portion of an array of memory cells of a memory device, in accordance with various embodiments.

FIG. 3 illustrates an example of an arrangement of an access line with a gate of an all-around gate transistor, in accordance with various embodiments.

FIG. 4 illustrates an example of an arrangement of an access line with a gate of an all-around gate transistor, in accordance with various embodiments.

FIG. 5 illustrates a top view of an example arrangement of all-around gate transistors of memory cells, which can be implemented with the structure of FIG. 2, in accordance with various embodiments.

FIG. 6 illustrates an embodiment of an example structure having a folded architecture in which memory cells having gate-all-around transistors can be implemented, in accordance with various embodiments.

FIG. 7 illustrates a top view of a representation of an open digit line architecture for one or more arrays of memory cells, where each memory cell includes a gate-all-around transistor coupled to a capacitor, in accordance with various embodiments.

FIG. 8 illustrates a structure having an arrangement of memory cells, where each memory cell has an access transistor and a capacitor, where the access transistor is a gate-all-around transistor, in accordance with various embodiments.

FIGS. 9-36 illustrate an example process flow of forming a memory device having the arrangement of memory cells of the structure of FIG. 8, in accordance with various embodiments.

FIG. 37 illustrates an example architecture in which the structure of FIG. 34 or similar structure can be located, in accordance with various embodiments.

FIG. 38 is a flow diagram of features of an example method of forming a memory device, in accordance with various embodiments.

FIG. 39 is a flow diagram of features of an example method of forming a memory device, in accordance with various embodiments.

FIG. 40 is a schematic of an electrical arrangement of components of an example dynamic random-access memory device that can include an architecture having hexagonal memory cells with gate-all-around transistors, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above and can be in a direction from the horizontal or to the horizontal. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In various embodiments, a memory device can be structured with an array of memory cells arranged as hexagonal cells, where each of the memory cells has a gate-all-around (GAA) transistor coupled to a capacitor. A hexagonal memory cell is a memory cell that is surrounded by six other memory cells such that the other memory cells are at vertices of a hexagonal structure formed by connecting the centers of adjacent memory cells of these other memory cells. A GAA transistor is a transistor structured with the gate of the transistor coupled with the channel structure of the transistor on all sides of the channel structure. The GAA transistor can be structured as a thin film transistor (TFT). The GAA transistor can be structured in a pillar arrangement containing active areas (source and drain) and the channel structure about which the gate is structured around. The pillar structure of the GAA transistor can be structured as a semiconductor nanowire. Nanowires are nanostructures having a diameter on the order of nanometers. A GAA nanowire transistor as an access device to a capacitor in memory cells of a DRAM can provide enhanced ION capability and flexible adjustment of transistor threshold voltage (V_{T}). ION is the on-state current of the transistor, where the current, IOFF, is the off-state current of the transistor. The ratio, ION/IOFF, is a figure of merit for high performance and low leakage power for the transistor. High performance is associated with more ION and low leakage power is associated with less IOFF.

The memory device, having one or more arrays of hexagonal memory cells of GAA transistors, can be implemented with control logic and sensing circuitry in a number of different architectures. The control logic and sensing circuitry can be located in a periphery region adjacent to an array of hexagonal memory cells on a wafer that is an IC chip. Another compatible architecture includes the control logic and sensing circuitry located under the one or more memory arrays in a circuit under array (CuA) architecture. The control logic and sensing circuitry can be arranged for sensing the programmed data states of memory cells of one or more memory arrays of the memory device and can enhance reduction of die size or increase utilization of space in a die or combination of dies. CuA refers generally to circuitry located in a memory die under a memory array of the memory die. With the control logic and sensing circuitry fabricated under the memory array using semiconductor processing that can include CMOS (Complementary Metal Oxide Semiconductor) processing technology, CuA can also be referred to as CMOS under array. Another compatible architecture can include control logic and sensing circuitry located above the memory arrays in a circuit over array (CoA) architecture. The control logic and sensing circuitry can be arranged for sensing the programmed data states of memory cells of one or more memory arrays of the memory device and can enhance reduction of die size or increase utilization of space in a die or combination of dies. CoA refers generally to circuitry located in a memory die over one or more memory arrays of the memory die. With the control logic and sensing circuitry fabricated over the one or more memory arrays using semiconductor processing that can include CMOS, CoA can also be referred to as CMOS over array. The CuA architecture and the CoA architecture can be implemented by a wafer-to-wafer architecture, where the control logic and sensing circuitry are formed on one wafer and the one or more memory arrays are formed on another wafer, with the two wafers combined. Wafer-to-wafer interconnect architectures can include a wafer-on-wafer architecture. Wafer-to-wafer bonding of back-to-back wafers with a CoA architecture can provide for the movement of a capacitor module for data storage in a DRAM to the bottom of the stack of wafers. This arrangement can reduce interconnect congestion between the stacked wafers.

The memory device can include a set of access lines (WLs), where each WL of the set of WLs can be coupled to gates of a first set of multiple GAA transistors of the memory cells of a memory array. Each WL can be formed with the formation of corresponding gates of GAA transistors in a replacement gate process, which can provide enhanced gate control. The memory device can include a set of digit lines (BLs), where each BL of the set of BLs can be coupled to a second set of multiple GAA transistors of the memory cells. Each of the BLs can be separated from an adjacent BL by an airgap. An airgap is a low-k dielectric. A low-k dielectric is a dielectric having a dielectric constant less than the dielectric constant of silicon dioxide. Dielectrics having a lower dielectric constant than silicon dioxide (dielectric constant of approximately 3.9) and silicon nitride (dielectric constant of approximately 7) can provide better isolation, resulting in less cross talk between metal lines. An airgap in a structure or between structures is a gap or region that is filled with air. Herein, the term airgap may include ambient gases enclosed in the gap, such as gases used or gas byproducts formed during formation of the gap. The airgap can have a dielectric constant equal to one. Additionally, each of the WLs can be separated from an adjacent WL by an airgap. Each BL can be at least partially wrapped on a sidewall of an active area of each GAA transistor of the second set. The BLs can be placed in the memory device angled at 90° relative to the WLs, where the BLs are vertically separated from the WLs.

The BLs can be damascene digits. In a damascene process, a dielectric is first formed on a structure and patterned, followed by metal formation filling the patterned dielectric. The metal formation can be realized by a process appropriate for the metal being formed, such as an appropriate metal deposition. Damascene digits can provide for better digit resistance.

The memory device can have a 4F² memory array configuration or an 8F² memory array configuration. Memory cell sizes are measured using an nF² formula where ‘n’ is a constant derived from the cell design and ‘F’ is the smallest feature size of the process technology. A unit repeating cell of a 4F² cell can be a parallelogram having sides of equal length of 2F. A unit repeating cell of a 8F² cell can be a parallelogram having sides of 2F and 4F. For the same feature size, as the cell size becomes smaller, memory capacity increases. In a 4F² memory cell configuration, the WL pitch and the BL pitch equal 2F.

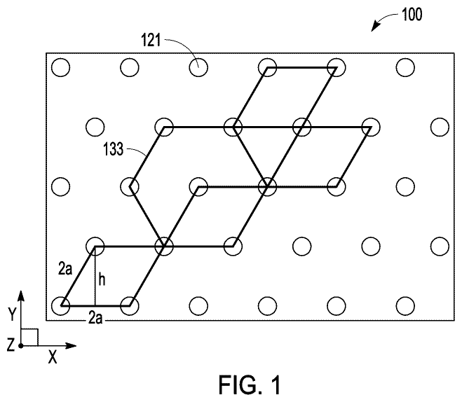

FIG. 1 illustrates a representation 100 of an embodiment of an example array of memory cells 121 arranged as hexagonal memory cells. One of similar multiple features in FIG. 1 and in subsequent figures may be labelled without labeling all similar features, for ease of presentation. Memory cells 121 are arranged as cells in the x-y plane with nearest neighbors forming a hexagon 133. Unit repeating cell of memory cell 121 is a parallelogram having sides of equal length of 2a and a height of h, with an area of 2 ah of approximately 3.46 a². Compared to a square unit repeating cell, having an area of 4a², the hexagonal cell can provide an approximately 13.4% smaller cell than a square cell in a 4F² architecture. Hexagonal memory cells having a GAA transistor as an access transistor can provide a relaxed critical dimension (CD) for BLs for memory cells sharing a BL in a 4F² architecture. In addition, GAA hexagonal 4F² cells can provide a larger WL pitch and shorter margins between nearest cells of different BLs than GAA square 4F² cells. WL pitch is a minimum distance between centers of adjacent WL lines in a set of WLs. A margin between two cells is a minimum distance between the two cells, which for cells with GAA access transistors, can be the distance between the outer boundary of the all-around gates of the GAA access transistors.

GAA transistors in an 8F² architecture can enable implementation of a folded BL architecture. In a folded BL array architecture, BLs are routed in pairs across the array. The close proximity of the paired BLs can provide superior common-mode noise rejection compared to open BL arrays. In open BL architectures, the BLs are divided into multiple segments and differential sense amplifiers (SAs), used to read the state of memory cell, are placed between the BL segments.

GAA hexagonal memory cells can be implemented in different three-dimensional compact architectures such as CoA and CuA architectures. GAA hexagonal memory cells, as taught herein, can provide for capacitor structures that allows the use of redistribution layers (RDLs) to be skipped. A typical DRAM uses RDL interconnect to rotate cell contact to a hexagonal form for a capacitor to land on. A capacitor is preferred in hexagonal form, because it has the highest surface area (hence the storage capacity) when it is hexagonal. Having a hexagonal active area, removes the need for patterning a hexagonal RDL module. In addition, airgap integration of BLs and WLs to GAA hexagonal cells can be straightforward, providing enhanced design control of BL capacitance and WL capacitance.

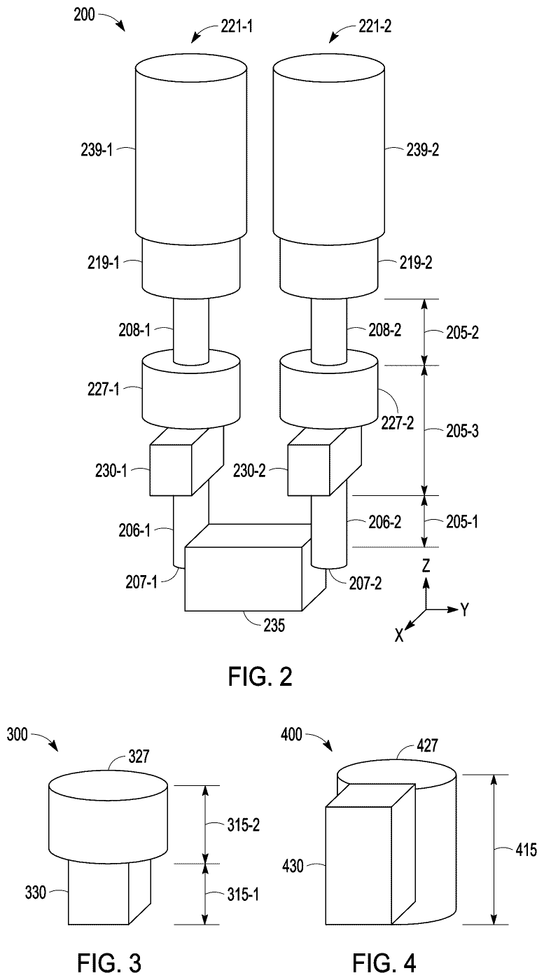

FIG. 2 illustrates an embodiment of an example structure 200 that can be arranged as a portion of an array of memory cells of a memory device. Structure 200 includes two vertical memory cells 221-1 and 221-2, where each memory cell has a GAA transistor coupled to a capacitor. Memory cell 221-1 includes a GAA transistor realized by a pillar 207-1 providing a channel around which an all-around gate 227-1 is positioned above an active area 206-1 of pillar 207-1 and below an active area 208-1 of pillar 207-1. The GAA transistor of memory cell 221-1 can be coupled to a capacitor 239-1 of memory cell 221-1 by a cell contact 219-1 that can be located around a junction of an active area 208-1. Memory cell 221-2 includes a GAA transistor realized by a pillar 207-2 providing a channel around which an all-around gate 227-2 is positioned above an active area 206-2 of pillar 207-2 and below an active area 208-2 of pillar 207-2. The GAA transistor of memory cell 221-2 can be coupled to a capacitor 239-2 of memory cell 221-2 by a cell contact 219-2 that can be located around a junction of active area 208-2.

Memory cell 221-1 is coupled to a WL 230-1 by gate 227-1. Memory cell 221-2 is coupled to a WL 230-2 by gate 227-2. WL 230-1 and WL 230-1 are separate WLs in the array in which memory cell 221-1 and memory cell 221-2 are located. Memory cell 221-1 and memory cell 221-2 share a common BL 235. BL 235 can at least partially wrap around active area 206-1 and can at least partially wrap around active area 206-2.

Not shown in FIG. 2 are dielectric materials isolating electronic components of memory cells 221-1 and 221-2 where appropriate. Though not shown, separation of WL 330-1 and WL 330-2 from each other can include an airgap. BL 235 can be separated from an adjacent BL of the memory device by an airgap. Additionally, BLs separate from BL 235 and airgaps are not shown in FIG. 2 to focus on the relative arrangement of memory cell 221-1 and memory cell 221-2. Optionally, though not shown, separation of BL 235 from additional BLs can include a digit shield, which is a conductive structure.

Pillars 207-1 and 207-2 can be implemented as nanowires. Pillar pitch can vary, but is not limited to, a range from approximately 28 nm to approximately 50. With WL 230-1 and WL 230-2 contacting or integrated with gates 227-1 and 227-2, respectively, WL height 205-3 can be about 50% larger that junction height 205-1 for active areas 206-1 and 206-2 and junction height 205-2 for active areas 208-1 and 208-2. Different relative heights can be implemented depending on the application.

FIG. 3 illustrates an embodiment of an example arrangement 300 of a WL 330 with a gate 327 of a GAA transistor. WL 330 can contact gate 327 at a bottom portion of arrangement 300. WL 330 can have, but is not limited to, a height 315-1 that is equal to a height 315-2 of gate 327. Alternatively, though not shown, WL 330 can contact gate 327 at a top portion of arrangement 300.

FIG. 4 illustrates an embodiment of an example arrangement 400 of a WL 430 with a gate 427 of a GAA transistor. WL 430 is substantially attached along the side of gate 427. WL 430 can be integrated with gate 427 in fabrication. Height 415 of WL 430 can be, but is not limited to, the height of gate 427 or substantially equal to the height of gate 427. Height 415 can be smaller than the sum of heights 315-1 and 315-2 of FIG. 3.

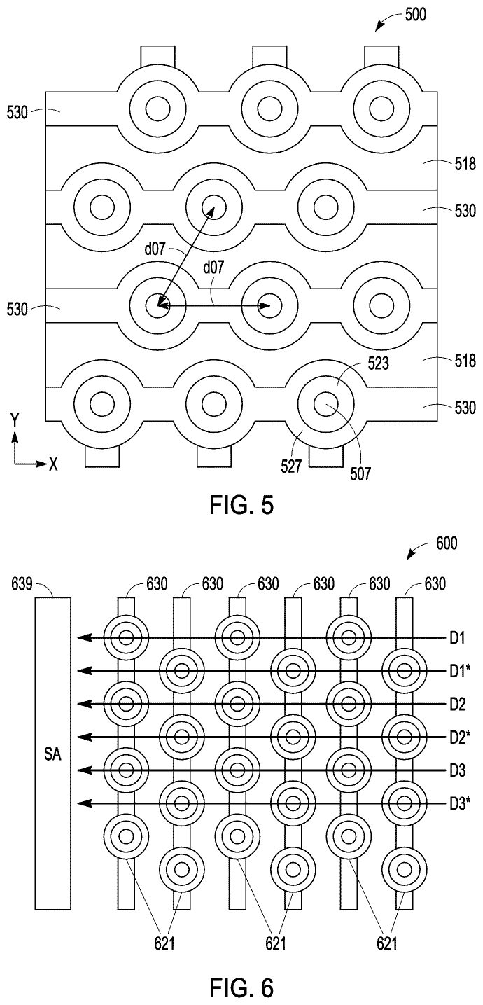

FIG. 5 illustrates a top view of an embodiment of an example arrangement 500 of GAA transistors of memory cells, which can be implemented with structure 200 of FIG. 2. Each transistor includes a vertical channel 507 surrounded by a gate dielectric 523, where gate dielectric 523 separates vertical channel 507 from all-around gate 527. A WL 530 is coupled to each GAA transistor of a given set of GAA transistors. Vertical channel 507 can be, but is not limited to, a polysilicon channel and gate dielectric 523 can be an oxide. All-around gate 527 and WL 530 can be metal structures. The coupling of a given set GAA transistors and a specific WL 530 can be implemented using arrangement 300 of FIG. 3 or arrangement 400 of FIG. 4.

The center of a WL 530 can align with the centers of the active areas of the GAA transistors, which can be structured as the center of the pillar providing channel 507. A WL 530 is not shared with a directly adjacent memory cell, where separation from the directly adjacent memory cell is provided by a dielectric 518. Dielectric 518 separates each of WLs 530 from each other. Along a given WL 530, multiple GAA transistors of a set of GAA transistors are configured in a substantially linear arrangement, where GAA transistors adjacent the multiple GAA transistors of the set are not electrically coupled to the given WL 530. The directly adjacent GAA transistor in the directly adjacent WL 530 can be separated from the GAA transistor in the given WL 530 by a distance d07 that can be equal to the separation from the directly adjacent GAA transistor in the same given WL 530. With the pillar for the channel 507 being a nanowire, the dimensions of the components of the GAA transistors and direct separations of GAA transistors can be of the order of nanometers or tens of nanometers.

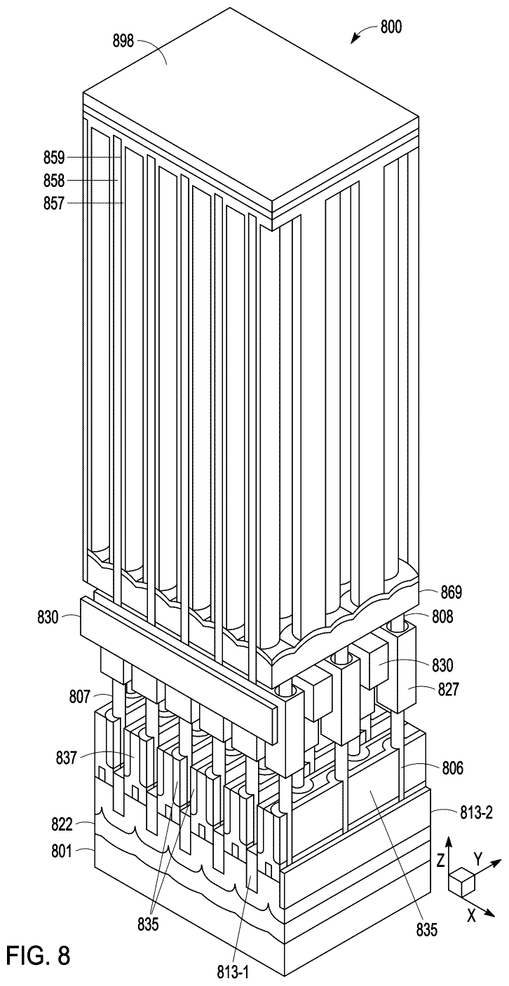

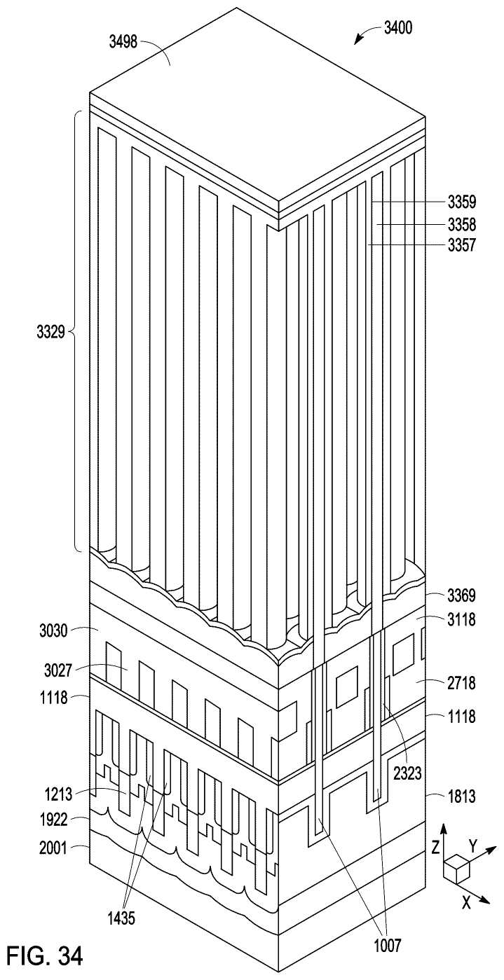

FIG. 6 illustrates an embodiment of an example structure 600 having a folded architecture in which memory cells having GAA transistors can be implemented. Structure 600 can include an array of memory cells 621. Different sets of memory cells 621 are coupled to different WLs 630. Each WL 630 is electrically coupled to a set of memory cells and each WL 630 is not shared with adjacent bits, where a bit is stored in a memory cell 621, that are in another set of memory cells electrically coupled to an adjacent WL 630. In the folded architecture, BLs are routed in pairs across the array, where the pairs can include D1 and D1*, D2 and D2*, D3 and D3*, and other pairs. Each pair of BLs can be next to each other and pulled to the same SA from the same array patch. A patch, which can also be referred as a mat, is a structure for a sub-array of memory cells of a larger memory array of a memory device such as the example structure 800 of FIG. 8 and example structure 3400 of FIG. 34. An folded BL architecture can also be referred to as a folded SA architecture. Each BL of these pairs is electrically coupled to a set of memory cells and each BL is not shared with adjacent bits that are in another set of memory cells electrically coupled to an adjacent WL 630. In addition, each memory cell is coupled to one WL 630 and one BL of one of the pairs of BLs, as indicated in FIG. 6. The pairs of BLs are routed to a SA 639 to read the state contained in a selected memory cell. An 8F² architecture of GAA transistor-based memory cells can be implemented with the data topology of a folded BL architecture with a separate WL and a separate BL for every bit. A folded bit line is favorable due to its reduced array noise.

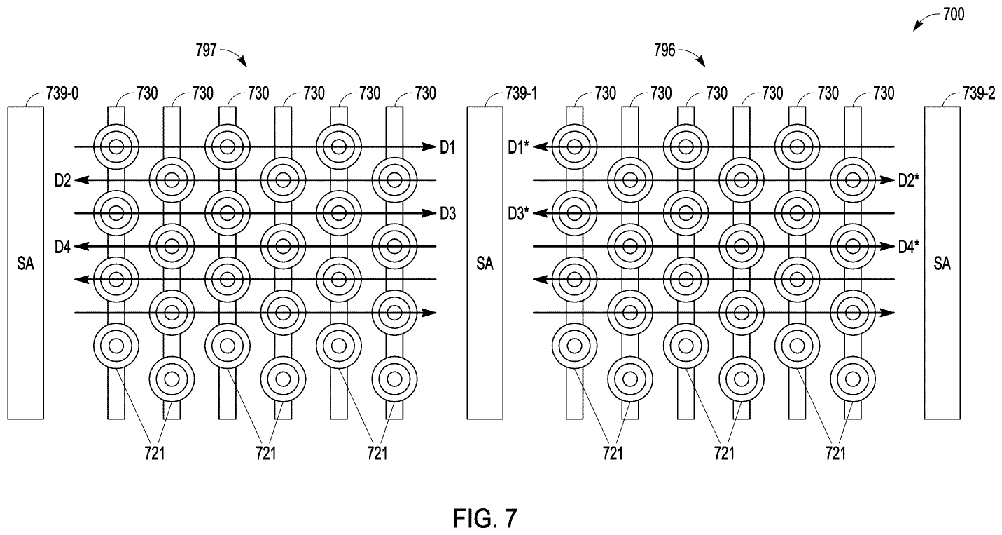

FIG. 7 shows a representation 700 of an open BL architecture, where each memory cell includes a GAA transistor coupled to a capacitor. The BLs are located on a different physical level of the memory device from the WLs. In an open BL architecture, the BLs are divided into multiple segments and differential SAs are placed between BL segments. BLs can be taken in pairs, where the BLs are taken from different patches. Each path can be realized by a different memory array structure including structure 800 of FIG. 8. An open BL architecture can be referred to as an open SA architecture. The open BL architecture of representation 700 can include SA 739-0, 739-1, and 739-2 in different portions of the memory device structure. BLs D1, D2, D3, and D4 are in region 797, which includes multiple WLs, with each WL 730 not shared with any adjacent bits. For example, region 797 can include each WL 730 having a set of multiple memory cells 721, where adjacent memory cells 721 to a given WL 730 are not addressed by the given WL 730. Each WL 730 can be integrated with a gate of GAA transistor of each memory cell 121 of the set of multiple memory cells 721 that the given WL 730 can address. BLs D1*, D2*, D3*, and D4* are in region 796, which includes multiple WLs 730, with each WL 730 not shared with any adjacent bits. For example, region 796 can include each WL 730 having a set of multiple memory cells 721, where adjacent memory cells 721 to a given WL 730 are not addressed by the given WL 730. Each WL 730 can be integrated with a gate of GAA transistor of each memory cell 121 of the set of multiple memory cells 721 that the given WL 730 can address.

BLs D1 and D3 can be coupled to SA 739-1, which can be referred to as an odd SA, and BLs D2 and D4 can be coupled to SA 739-0, which can be referred to as an even SA. BLs D1* and D3* can be coupled to SA 739-1, and BLs D2* and D4* can be coupled to SA 739-2, which can be referred to as an even SA. Regions 797 and 796 can be formed in individual subtractive processes. A subtractive process includes removing material from a solid block of starting material.

FIG. 8 illustrates a structure 800 having an arrangement of memory cells, where each memory cell has an access transistor and a capacitor, where the access transistor is a GAA transistor coupled to a BL, with separation of the BL from a directly adjacent BL having an airgap. Various dielectric regions are not shown to focus on active components of structure 800. The memory cells are arranged on a wafer 801, which can be referred to as an array wafer 801, since the memory cells are structured at a level above wafer 801. A bonding dielectric 822 is positioned on array wafer 801, where the bonding dielectric 822 is structured to bond to array wafer 801 during the formation of the memory cells. A dielectric 813-2 is located on bonding dielectric 822. BLs 835 are positioned above bonding dielectric 822 and above dielectric 813-1. Each BL 835 is separated from a directly adjacent BL by an airgap 837.

Semiconductor pillars 807 extend above about a level at the top of dielectric 813-2. Semiconductor pillars 807 can be realized as nanowires. Each semiconductor pillar 807 includes a channel between two source/drain regions. For each semiconductor pillar 807, a gate dielectric, at shown, is positioned around the channel provided by semiconductor pillar 807. A gate 827 is positioned around each gate dielectric and semiconductor pillar 807 with an WL 830 contacting gate 827. Gate 827 and WL 830 can be structured in a format with WL 830 integrated with multiple gates 827, as shown in the x-direction of FIG. 8. The two source/drain regions of each semiconductor pillar 807 are active areas. Each active area can include a contact junction. For each semiconductor pillar 807, the channel is coupled to a capacitor by active area 808 having a cell contact junction and is coupled to a BL 835 by an active area 806 having a digit contact junction (a digit contact can be referred to as a bit contact or bitcon). Each BL 835 can be at least partially wrapped on a sidewall of active area 806, which provides the BL integrated with the memory cell. Active area 806 and BL 835 can be structured in a format with BL 835 integrated with active areas 806, as shown in the y-direction of FIG. 8. Bitcon junction areas can be configured as shields to reduce the capacitance between the BLs. Alternatively, digit shields can optionally be structured between adjacent BLs 835.

A dielectric 869 is located above WLs 830 and gates 827. Dielectric 869 results from the processing of structure 800 and provides electric isolation to conductive components in structure 800. Above dielectric 869 are a set of capacitors 829. Each capacitor 829 includes a capacitor dielectric 859 between two electrodes 857 and 858. Electrode 858 can be referred to as a bottom electrode that is coupled to active area 808 of semiconductor pillar 807, while electrode 857 is a top electrode that can be coupled to a reference node. Capacitor dielectric can be, but is not limited to, a high-k dielectric. A high-k dielectric is a dielectric having a dielectric constant greater than the dielectric constant of silicon dioxide. Structure 800 can include a dielectric region 898 or connecting wafer on the set of capacitors 829.

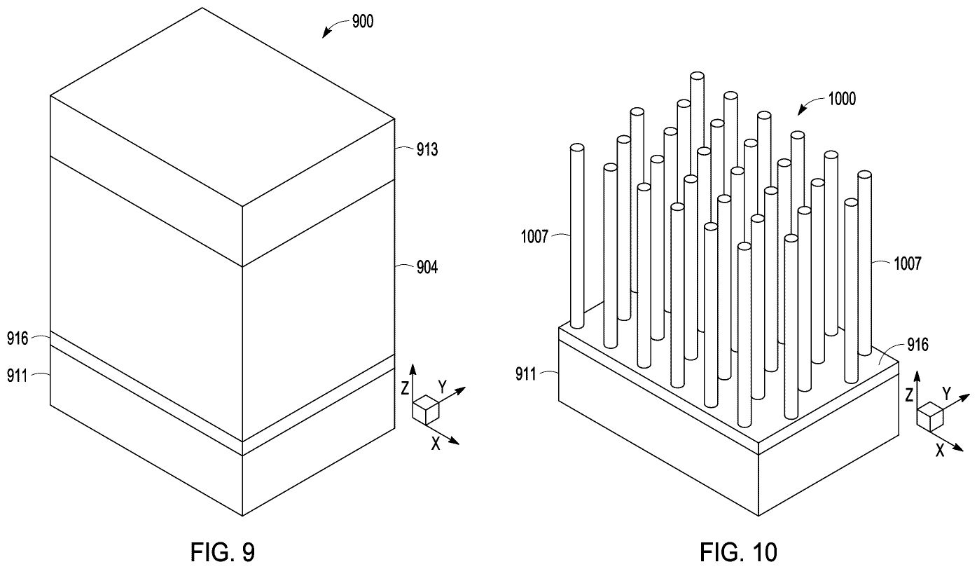

FIGS. 9-36 illustrate an embodiment of an example process flow of forming a memory device having an arrangement similar to the arrangement of memory cells of structure 800 of FIG. 8. The memory cells can be arranged with a 4F² architecture or an 8F² architecture. For the procedures discussed herein, the selection of processing materials can depend on the materials selected to form various components of and contacts to components of the memory device. The processing materials can be selected to allow removal of one or more materials, while retaining one or more other materials. In addition, deposition techniques can be used that are typical for the material being formed, the dimensions of the material being formed, and the architecture in which the material is being formed.

FIG. 9 shows a structure 900 after a block of material has been formed on a substrate 911. The block can be semiconductor material. For example, the block can be formed with a layer 916 of silicon germanium (SiGe) on substrate 911, where substrate 911 can be a silicon substrate. The SiGe can be 15% SiGe that can be formed by an appropriate deposition process. Materials other than SiGe can be used. The thickness of the SiGe from substrate 911 can be, but is not limited to, a range between approximately ten to twenty nanometers. Formation of the block of material can include a layer 904 of epitaxial Si formed on the SiGe. Materials other than epitaxial Si can be used. The thickness of the epitaxial Si on the SiGe can be, but is not limited to, a range between approximately 150 nm and 300 nm. Formation of epitaxial Si can be followed by formation of a hard mask 913 on the epitaxial Si. A hard mask is a material that can be used as a etch mask in an etch process, where the material is different from a polymer or other relatively soft material such as relatively soft resist materials. A hard mask is typically a high-density material used in the etch process to protect certain areas of a structure being processed from the etching chemicals being used in the etch process.

FIG. 10 shows a structure 1000 after processing structure 900 of FIG. 9. Channels for GAA transistors have been patterned and formed as pillars 1007 from layer 904, with the removal of portions of layer 904 that leaves layer 916 or portions of layer 916. Alternatively, portions of layer 904 of structure 900 can remain with layer 916 in a base to pillars 1007 from the processing of forming pillars 1007. With layer 904 of structure 900 being epitaxial Si, pillars 1007 are pillars of epitaxial Si. Photolithography can be used in the patterning and forming of pillars 1007 using deep ultraviolet radiation (DUV) or extreme ultraviolet radiation (EUV). Pillars 1007 can be formed having, but is not limited to, channel diameters in the range of approximately 6 nm to 20 nm. The channels can be formed for the GAA access devices having diameters in range of approximately 20 nm to 50 nm. Other diameters can be used.

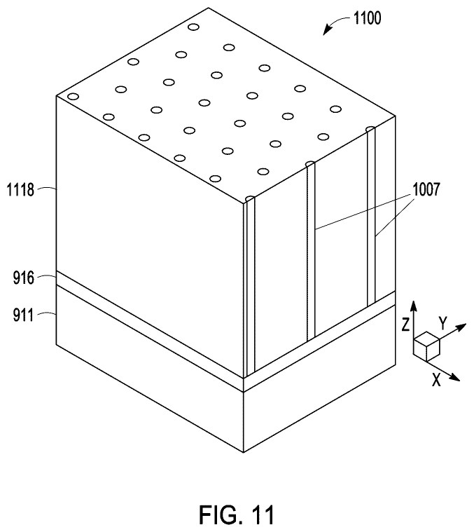

FIG. 11 shows a structure 1100 after processing structure 1000 of FIG. 10. A dielectric 1118 has been formed on layer 916 filling the spaces between pillars 1007. Dielectric 1118 and pillars 1007 have been subjected to a chemical mechanical polishing (CMP) process, leaving the top surfaces of pillars 1007 exposed in dielectric 1118. Dielectric 1118 can be formed by a deposition process suitable for the material of dielectric 1118. Dielectric 1118 can be an oxide such as, but not limited to, silicon oxide.

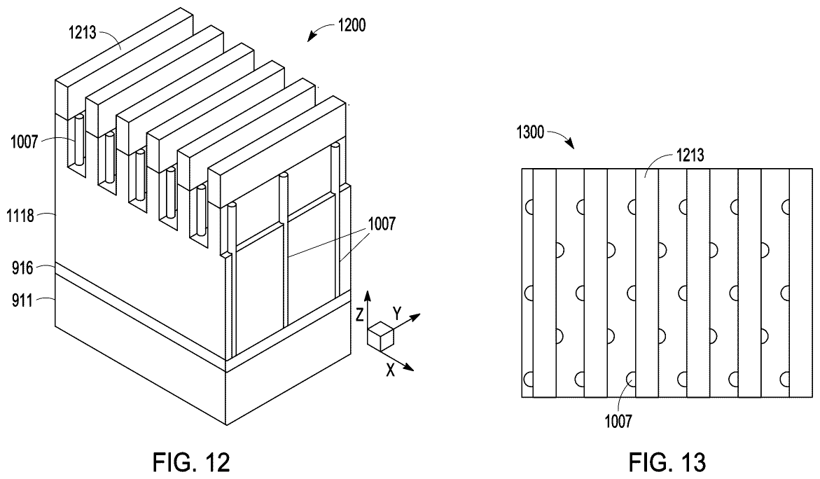

FIG. 12 shows a structure 1200 after processing structure 1100 of FIG. 11. A hard mask 1213 has been formed on the top surface of structure 1100 and patterned. Hard mask 1213 can be formed by deposition processes suitable for the materials of hard mask 1213. Hard mask 1213 has been patterned and portions of dielectric 1118 have been removed. The formed pattern provides a pattern for a damascene structure for forming BLs. Removal of portions of dielectric 1118 has exposed sidewalls of pillars 1007. The exposed sidewalls of pillars 1007 are processed as active areas for GAA transistors to be formed, where the exposed sidewalls are implanted to form junctions for bitcons to capacitors to be formed in the process flow for forming a memory device having the arrangement of memory cells of structure 800 of FIG. 8. After the implant process, the structure can be subjected to an implant clean process.

FIG. 13 shows a representation 1300 of a top view of structure 1200 of FIG. 12. The patterning of hard mask 1213 provides separated lines of hard mask 1213. Each line of hard mask 1213 is over a set of pillars 1007, where pillars 1007 are effectively arranged in a linear fashion in rows.

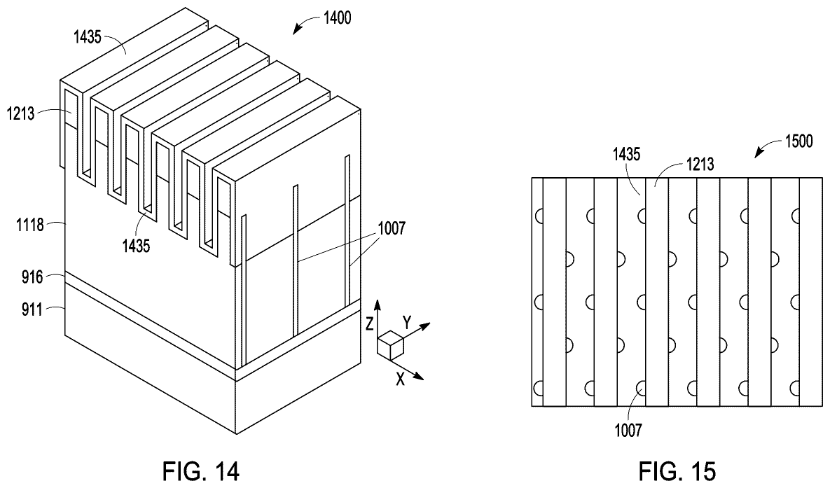

FIG. 14 shows a structure 1400 after processing structure 1200 of FIG. 12. Metal 1435 has been formed on hard mask 1213 and in spaces between lines of hard mask 1213, shown in FIG. 13, on the exposed surfaces of structure 1200. Formation of metal 1435 at the relevant locations can be made by a deposition process suitable for the metal being formed on the exposed surfaces of structure 1200. Metal 1435 can be formed at a spacing in the range of appropriately 7 nm to 12 nm.

FIG. 15 shows a representation 1500 of a top view of structure 1400 of FIG. 14. In this view, metal 1435 formed on top surfaces of hard mask 1213 are not shown to illustrate metal 1435 formed in the spaces between lines of hard mask 1213 and wrapping pillars 1007. Pillars 1007 are on the left and right sides of each line of hard mask 1213.

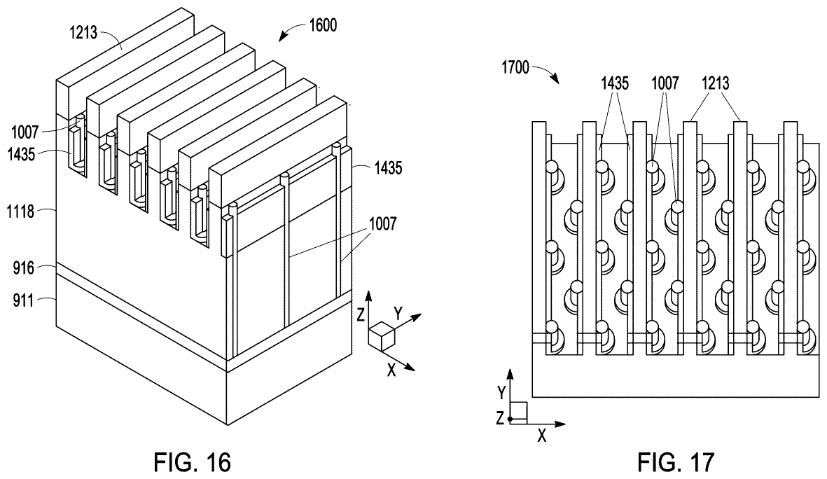

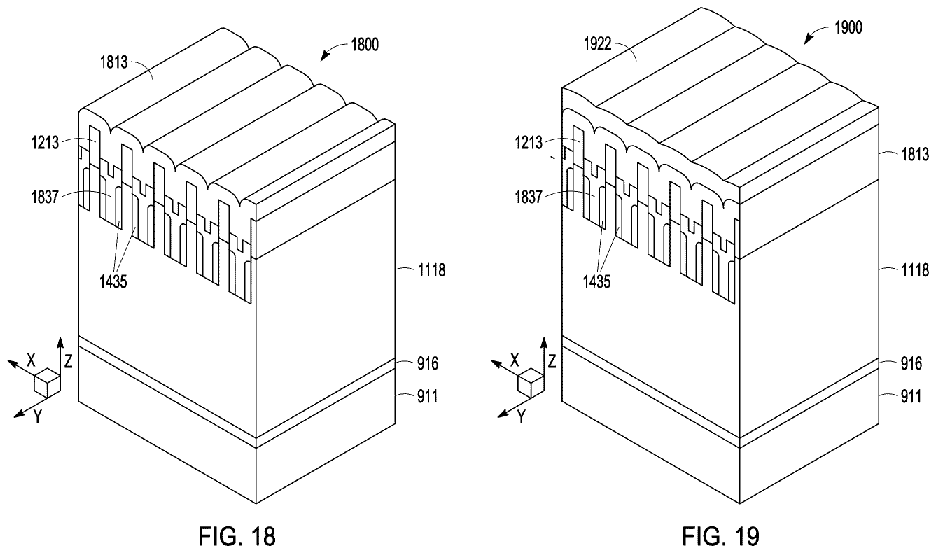

FIG. 16 shows a structure 1600 after processing structure 1400 of FIG. 14. Metal 1435 has been etched, punching through to form isolation trenches. FIG. 17 shows a representation 1700 of a top view of structure 1600 of FIG. 16. Lines of metal 1435 are formed on each side under lines of hard mask 1213. Metal 1435 is formed at least partially wrapping pillars 1007. FIG. 15 shows the isolation provided by a post metal punch, where metal 1435 is on the two sides of the isolation trench. There can be a smallest metal-to-metal space such as, but not limited to, approximately 5 nm.

FIG. 18 shows a structure 1800 after processing structure 1600 of FIG. 16. A dielectric 1813 has been formed on the exposed surfaces of structure 1600. Dielectric 1813 covers hard mask 1213 and metal 1435. Material of dielectric 1813 can be the same as the material of hard mask 1213. Formation of dielectric 1813 can be conducted using a deposition procedure appropriate for the material selected for dielectric 1813. The deposition procedure has been selected to provide airgaps 1837 between each line of metal 1435 and a directly adjacent line of metal 1435. In general, airgap formation can be performed based on non-conformal deposition, which pinches off the top of the patterned structure without filling-in the small trenches between the metal lines. A physical vapor deposition (PVD) that does not fill-in the high aspect ratio gap structures can provide an relatively inexpensive and straightforward way of forming an airgap. With dielectric 1813 being a nitride, a PVD can be used to deposit the nitride to pinch off the top of dielectric 1813 being formed.

FIG. 19 shows a structure 1900 after processing structure 1800 of FIG. 18. A bonding dielectric 1922 has been formed on dielectric 1813. Bonding dielectric 1922 can be buffed, subjected to a CMP process, and cleaned. Formation of bonding dielectric 1922 can be conducted using a deposition process appropriate for the material selected for bonding dielectric 1922. Material for bonding dielectric 1922 can be, but is not limited to, tetraethoxysilane (TEOS), silicon carbon nitride (SiCN), material for high aspect ratio process (HARP), or combinations of similar materials.

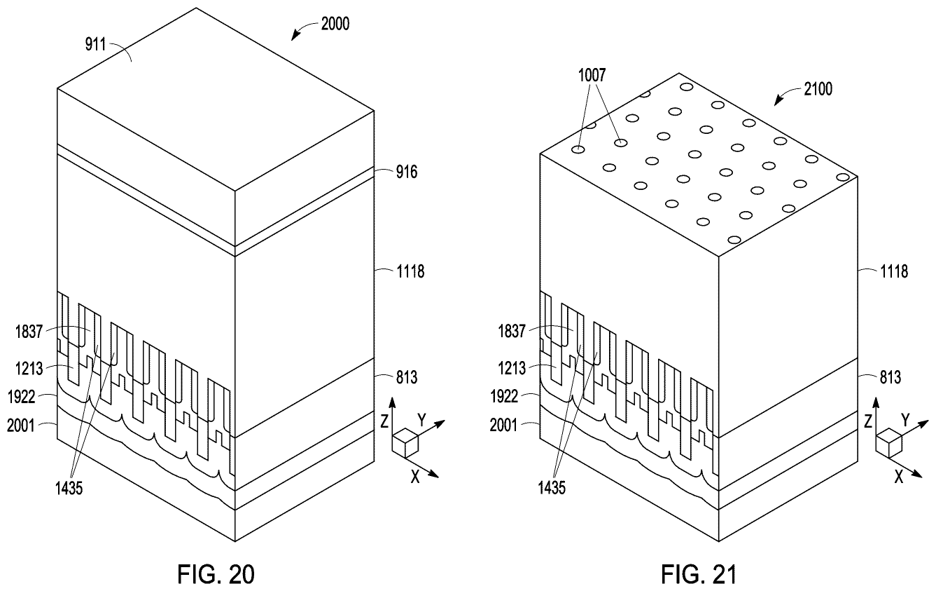

FIG. 20 shows a structure 2000 after processing structure 1900 of FIG. 19. Bonding dielectric 1922 has been bonded to a carrier wafer 2001 and the bonded structure is flipped, placing substrate 911 as the top of structure 2000. Carrier wafer 2001 can be an inexpensive wafer or a glass carrier with an oxide deposited surface. The bonding can be conducted through fusion bonding.

FIG. 21 shows a structure 2100 after processing structure 2000 of FIG. 20. Structure 2000 has been subjected to a CMP procedure that exposes tops of pillars 1007 that are being used for channels of GAA transistors being formed in the process flow. These tops of pillars 1007 will provide junctions of cell contacts to capacitors. Substrate 911 and layer 916 have been removed.

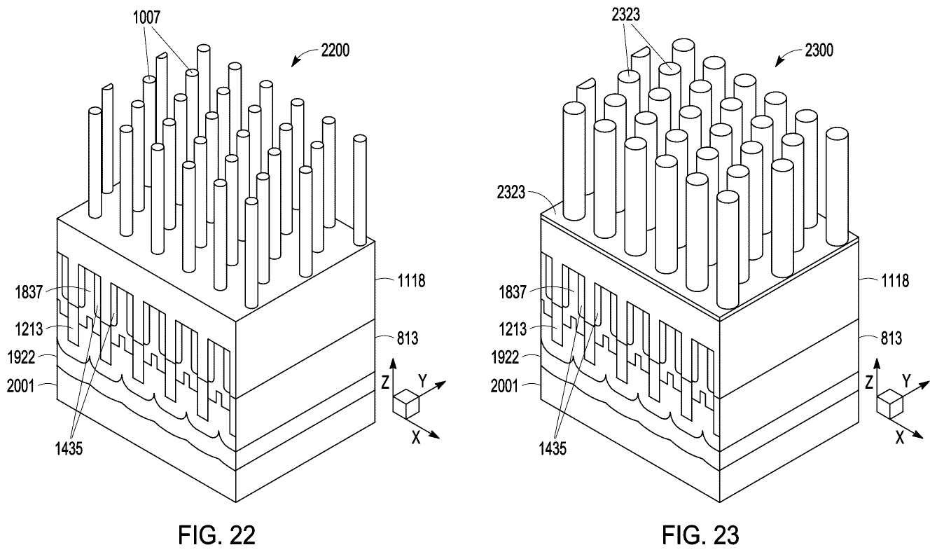

FIG. 22 shows a structure 2200 after processing structure 2100 of FIG. 21. Portions of dielectric 1118 have been selectively removed to a selected level of dielectric 1118, exposing pillars 1007. For dielectric 1118 being an oxide and pillars 1007 being silicon, oxide of dielectric 1118 can be recessed selective to a Si surface. A selective wet etch can be used for the purpose of the recess of dielectric 1118 to a specified level. The selective wet etch can be a time controlled etch.

FIG. 23 shows a structure 2300 after processing structure 2200 of FIG. 22. Dielectric material 2323 has formed on the exposed surfaces of structure 2200. Dielectric material 2323 covers the exposed portions of pillars 1007 and will provide a gate dielectric for GAA transistors being formed about pillars 1007. Dielectric material 2323 can be, but is not limited to, a gate oxide material. Dielectric material 2323 can be formed by a deposition procedure that is suitable for the selected material for dielectric material 2323. Alternatively, dielectric material 2323 can be formed by in-situ steam generation (ISSG), where an ISSG procedure includes generation of steam in close proximity to a wafer surface, providing a wet oxidation.

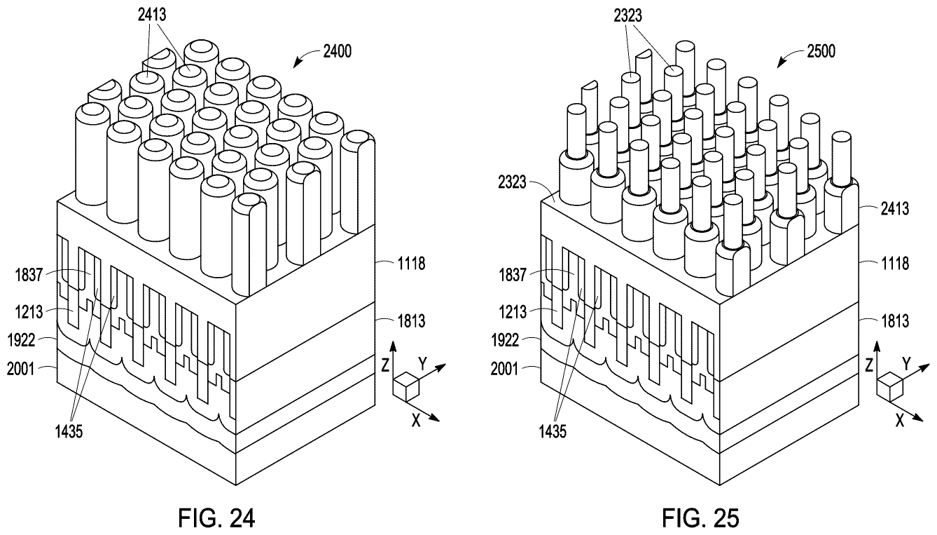

FIG. 24 shows a structure 2400 after processing structure 2300 of FIG. 23. A liner 2413 has been formed on the exposed structure 2300. Formation of liner 2413 can be conducted using a deposition procedure appropriate for the material of liner 2413. Liner 2413 can be, but is not limited to, a nitride liner. Liner 2413 is formed as a sacrificial liner in the process flow.

FIG. 25 shows a structure 2500 after processing structure 2400 of FIG. 24. Liner 2413 has been selectively etched back exposing portions of dielectric material 2323. The surface regions of structure 2400 have been filled with a dielectric such as, but not limited to, an oxide, subjected to a CMP procedure, and dry etched to expose the portions of dielectric material 2323. The dry etch can be selective to dielectric material 2323 being a high-k dielectric or a gate oxide.

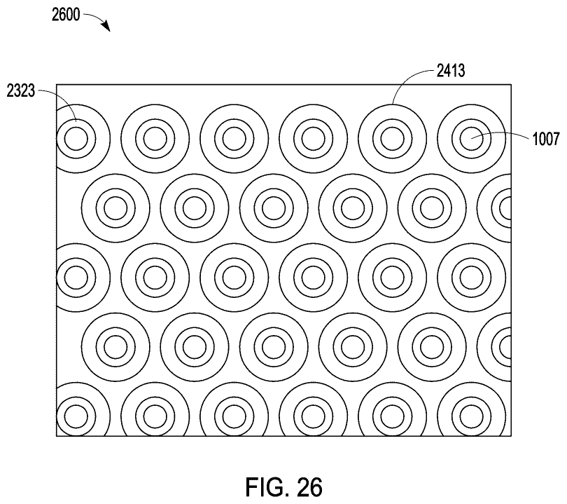

FIG. 26 shows a representation 2600 of a top view of structure 2500 of FIG. 25. FIG. 26 shows an array of cells being formed. Each cell represented includes a center pillar 1007, providing a channel, surrounded by dielectric material 2323, provided as gate material, where dielectric material 2323 is surrounded by liner 2413.

FIG. 27 shows a structure 2700 after processing structure 2500 of FIG. 25. A photolithographic procedure has been conducted for preparing WLs. A dielectric 2718 has been formed on the exposed surfaces of structure 2500 of FIG. 16. A carbon-based hard mask 2728 has been applied to the surface of dielectric 2718 and has been selectively removed down to a top surface of dielectric 2718. A dry etch can be used to form the pattern of carbon-based hard mask 2728 shown in FIG. 27.

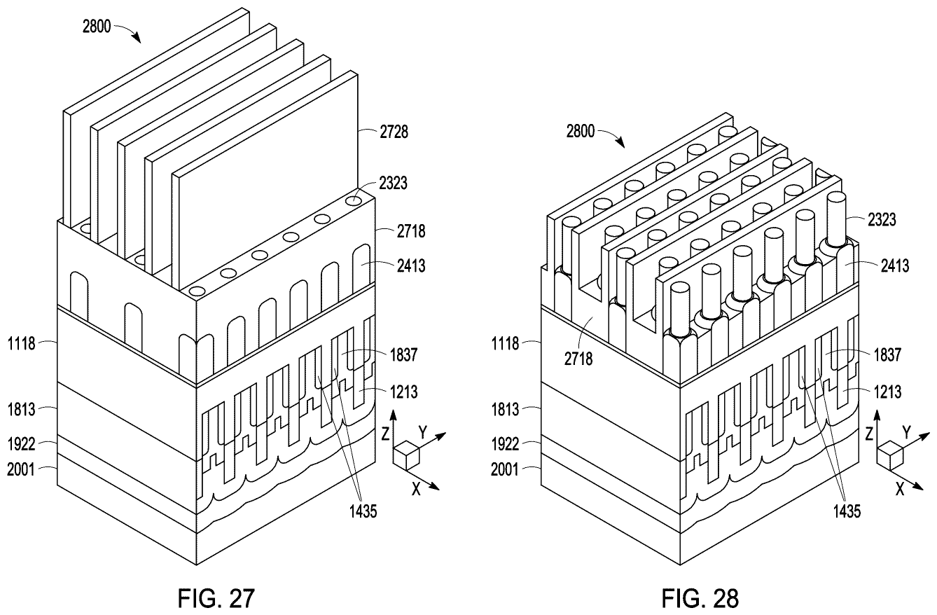

FIG. 28 shows a structure 2800 after processing structure 2700 of FIG. 27. Carbon-based hard mask 2728 has been stripped. An etch has removed most of dielectric 2718, exposing the tops of liners 2413 and dielectric material 2323 above liners 2413.

FIG. 29 shows a structure 2900 after processing structure 2800 of FIG. 28. Liners 2413 have been selectively removed, where liners 2413 were formed as a sacrificial liners. With liner 2413 being a sacrificial nitride, the removal procedure can include removing liner 2413 using a wet etch selective to maintain dielectric material 2323 and lower portions of dielectric 2718. For example, the selective etchant can include a hot phosphide. The removal procedure has maintained regions of dielectric 2718 positioned to provide insolation between sets of linearly arranged pillars covered by dielectric material 2323.

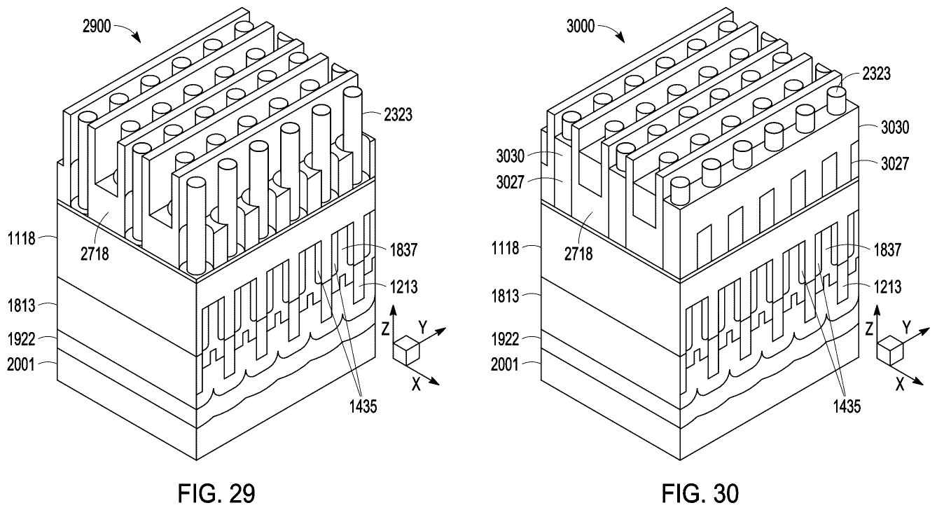

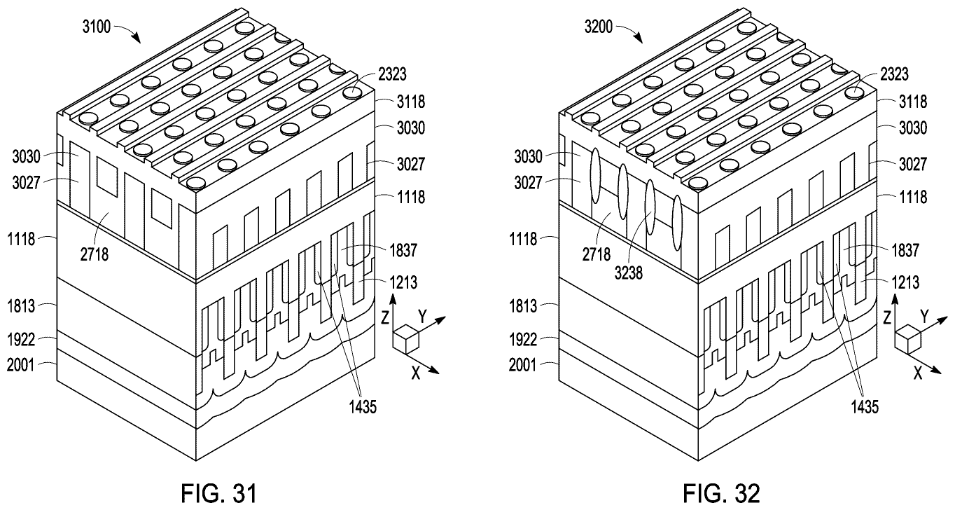

FIG. 30 shows a structure 3000 after processing structure 2900 of FIG. 29. Conductive material 3027 has been formed for gates and conductive material 3030 has been formed for WLs. Conductive material 3027 can be formed as metal deposited to form gates of GAA transistors and conductive material 3030 can be formed as metal deposited to form the WLs. The formed conductive material 3030 has been recessed back to form the shape of conductive material 3030 as shown in FIG. 30.

FIG. 31 shows a structure 3100 after processing structure 3000 of FIG. 30. Dielectric 3118 has been formed as a partial fill, followed by performing a wet recess. Dielectric 3118 can be, but is not limited to, an oxide. The junctions of the cell contacts of pillars 1007 have been implanted for coupling to capacitors. The implants can be n+ implants.

FIG. 32 shows a structure 3200 after optionally processing structure 3000 of FIG. 30 to form an airgap between conductive material 3030 for WLs and a directly adjacent conductive material 3030 for a WL. Dielectric 3118 use been formed as a nonconformal dielectric seal, leaving airgap 3238 adjacent. Dielectric 3118 have been recessed.

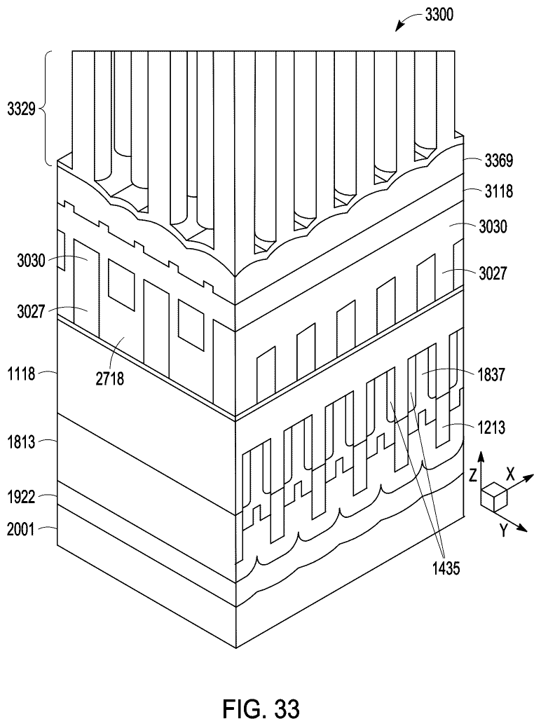

FIG. 33 shows a structure 3300 after processing structure 3100 of FIG. 31. An etch stop 3369 has been formed. Etch stop 3369 can be formed by a deposition procedure appropriate for the material used for the etch stop 3369. Etch stop 3369 can be a nitride etch stop. A set of capacitors 3329 has been formed on etch stop 3369. A similar process flow can be performed if structure 3200 of FIG. 32 is constructed.

FIG. 34 shows a structure 3400 after processing structure 3300 of FIG. 33. A cover layer 3498 has been formed on the top of the set of capacitors 3329. In forming the capacitors, bottom electrodes 3358 have been formed coupled to pillars 1007. Top electrodes 3357 have been formed, separated from bottom electrodes 3358 by capacitor dielectrics 3359. Capacitor dielectrics 3359 can be formed, but are not limited to, high-k dielectrics. The capacitor process can be implemented using the same mask-set that was used to pattern the area areas. The capacitor module can be aligned on the junction of the cell contact-active area-channel arrangement provided by pillars 1007. Structure 3400 provides an array structure that is ready to be processed with control and sensing circuitry of a memory device such as a DRAM device. Cover layer 3498 can be a wafer used to mount structure 3400 for coupling to the control and sensing circuitry.

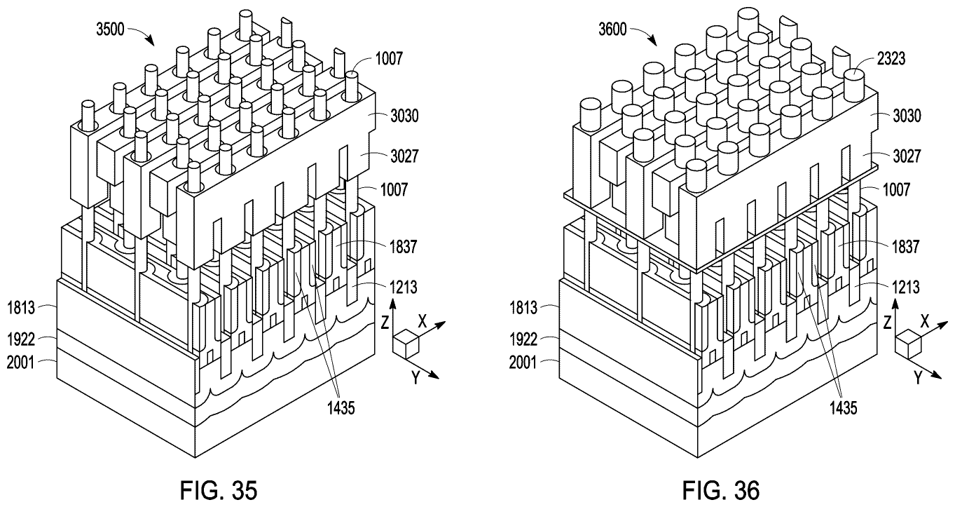

FIGS. 35-36 show details of structure 3400 of FIG. 34. Structure 3500 shows the region of structure 3400 below the capacitors 3329 of FIG. 34. To provide a more detailed view of structure 3400, various dielectric layers formed in the fabrication of structure 3400 are not shown in structure 3500 of FIG. 35. Metal 1435 of digital lines are at least partially wrapped around junction cell contacts of active areas 3506 of GAA transistors having channel formed by pillars 1007. Formed around pillars 1007s are conductive material 3027 for gates of the GAA transistors, where conductive material 3027 for gates contact metal 3030 for WLs. Though not shown in FIG. 35, pillars 1007 include junction bitcon contacts of active areas of the GAA transistors contacting electrodes 3358 of capacitors 3329 of the memory cells of structure 3400.

FIG. 36 shows a representation 3600 of structure 3500 with portions of metal 3030 removed to illustrate dielectric material 2323 for gate dielectrics of the GAA transistors formed in the process flow of FIGS. 8-34. Metal 1435 of structure 3400 can be referred to as BLs 1435. BLs 1435 are separated from each other, with each BL 1435 contacting multiple memory cells by contacting multiple pillars 1007. A BL 1435 is separated from an adjacent BL 1435 by an airgap 1837. WLs 3030 contact conductive material 3027 for gates of the GAA transistors arranged as access devices to capacitors of structure 3400.

The process flow of FIGS. 8-36 provides a number of enhancements to memory devices such as DRAM devices. WLs can be formed as replacement gates of GAA transistors, which can provide enhanced gate control. The capacitor formation of this process flow allows the use of RDLs to be skipped.

Various deposition techniques for components in the process flows discussed herein can be used that are typical for the material being formed, the dimensions of the material being formed, and the architecture in which the material is being formed in the fabrication of the memory device. Material and structures can be formed by a suitable process such as, but not limited to, a deposition process, where the deposition process can include, but not be limited to, PVD, chemical vapor deposition (CVD), atomic layer deposition (ALD), or other deposition process. Other processes can be used. Selective etching can be used to remove selected regions in the processing discussed with respect to the process flows. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods include a number of different etching procedures. In addition, conventional masking techniques, providing protective regions in the processing, can be used in removal of selected regions in forming the components of the memory device.

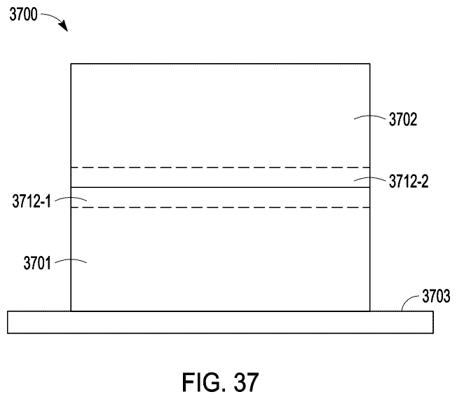

FIG. 37 illustrates an embodiment of an example architecture 3700 in which structure 3400 of FIG. 34 or a similar structure can be located. Architecture 3700 is structured as a wafer-to-wafer interconnect architecture, which includes a control wafer 3702 having a bonding region 3712-2 attached to an array wafer 3701 having a bonding region 3712-1. The combination of control wafer 3702 attached to array wafer 3701 can be mounted on a carrier wafer 3703 or other appropriate platform. Control wafer 3702 can be attached to array wafer 3701 by conducting a bonding of bonding region 3712-1 to bonding region 3712-2. The bonding process can be conducted through fusion bonding. Array wafer 3701 can include one or more of structures 3400 or similar structures having one or more arrays of memory cells. Control wafer 3702 can include control and sensing circuitry for operation of arrays of memory cells of the one or more structures 3400 of array wafer 3701 in a CoA architecture. Alternatively, the vertical order on carrier wafer 3703 of control wafer 3702 attached to array wafer 3701 can be reversed, configuring architecture 3700 as a CuA architecture.

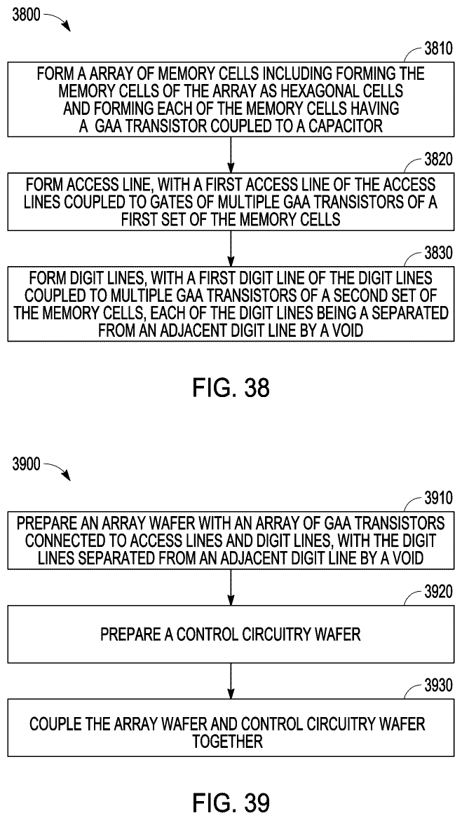

FIG. 38 is a flow diagram of features of an embodiment of an example method 3800 of forming an memory device. At 3810, an array of memory cells is formed. The memory cells of the array are formed as hexagonal cells. Each of the memory cells are formed having a GAA transistor coupled to a capacitor. At 3820, WLs are formed, with a first WL of the WLs coupled to gates of multiple GAA transistors of a first set of the memory cells. At 3830, BLs are formed. A first BL of the BLs is coupled to multiple GAA transistors of a second set of the memory cells. Each of the BLs is formed separated from an adjacent BL by an airgap. The formation of the memory cells, WLs, and BLs can be an integrated procedure.

Variations of method 3800 or methods similar to method 3800 can include a number of different embodiments that may be combined depending on the application of such methods and/or the architecture of systems including a memory device for which such methods are implemented. Such methods can include forming vertical nanowires extending above a substrate, with the vertical nanowires having channel structures around which gates of the GAA transistors are formed. The vertical nanowires can include epitaxial silicon formed on silicon germanium above a silicon substrate.

Variations of method 3800 or methods similar to method 3800 can include performing a number of procedures in forming the memory device. Vertical semiconductor pillars for the GAA transistors can be formed, where the vertical semiconductor pillars extend above a substrate. A dielectric can be formed between the vertical semiconductor pillars and a damascene structure can be performed on the dielectric. Metal, for the BLs of the set, can be formed wrapped at least partially on sidewalls of the vertical semiconductor pillar. A top dielectric, covering the metal, can be formed, pinching off the top dielectric and forming airgaps adjacent the BLs. Variations can include forming the top dielectric by forming a nitride using a PVD.

Variations can include performing a number of other procedures. A bonding dielectric can be formed on the top dielectric and attached to a carrier wafer. The carrier wafer can be arranged as a bottom structure with the metal, covered by an isolation dielectric surrounding the vertical semiconductor pillars, arranged above the carrier wafer. Gate dielectrics and all-around gates for the GAA transistors can be formed above the isolation dielectric. The gate dielectrics can be formed as a deposited high-k dielectric or formed as an oxide by in-situ steam generation on the vertical semiconductor pillars.

FIG. 39 is a flow diagram of features of an embodiment of an example method of forming an memory device. At 3910, an array wafer can be prepared with an array of GAA transistors connected to WLs and BLs, with the BLs separated from an adjacent BL by an airgap. At 3920, a control circuitry wafer is prepared. At 3930, the array wafer and the control circuitry wafer are coupled together. The coupling can be realized by a fusion bonding procedure.

Variations of method 3900 or methods similar to method 3900 can include a number of different embodiments that may be combined depending on the application of such methods and/or the architecture of systems including a memory device for which such methods are implemented. Such methods can include forming each WL separated from an adjacent WL by a second airgap. Variations can include forming the array of GAA transistors as hexagonal memory cells in a 4F² architecture or an 8F² architecture.

In various embodiments, a memory device can comprise an array of memory cells arranged as hexagonal cells. Each of the memory cells can have a GAA transistor coupled to a capacitor. WLs can have a first WL coupled to gates of multiple GAA transistors of a first set of the memory cells. BLs can have a first BL coupled to multiple GAA transistors of a second set of the memory cells, where each of the BLs can be separated from an adjacent BL by an airgap.

Variations of such a memory device and its features, as taught herein, can include a number of different embodiments and features that can be combined depending on the application of such memory devices, the format of such memory devices, and/or the architecture in which such memory devices are implemented. Variations of such memory devices can include each WL separated from an adjacent WL by a second airgap. Variations can include the multiple GAA transistors of the first set configured in a substantially linear arrangement and GAA transistors adjacent the multiple GAA transistors of the first set not coupled to the first WL. Variations can include the multiple GAA transistors of the second set configured in a substantially linear arrangement and GAA transistors adjacent the multiple GAA transistors of the second set not coupled to the first BL.

Variations of such a memory device can include the first BL coupled to a first sense amplifier and a second BL, directly adjacent the first BL, coupled to a second sense amplifier. Variations can include the first BL being at least partially wrapped on a sidewall of an active area of each GAA transistor of the second set. Variations can include the array of memory cells having an 8F² cell configuration.

Variations of such a memory device can include the memory device having control logic and sensing circuitry above the array. Variations can include the control logic and sensing circuitry and the array of memory cells arranged in a wafer-to-wafer interconnect architecture. Wafer-to-wafer interconnect architectures can include a wafer-on-wafer architecture. Variations can include a channel structure and active areas of the GAA transistor of a memory cell structured in a vertical nanowire.

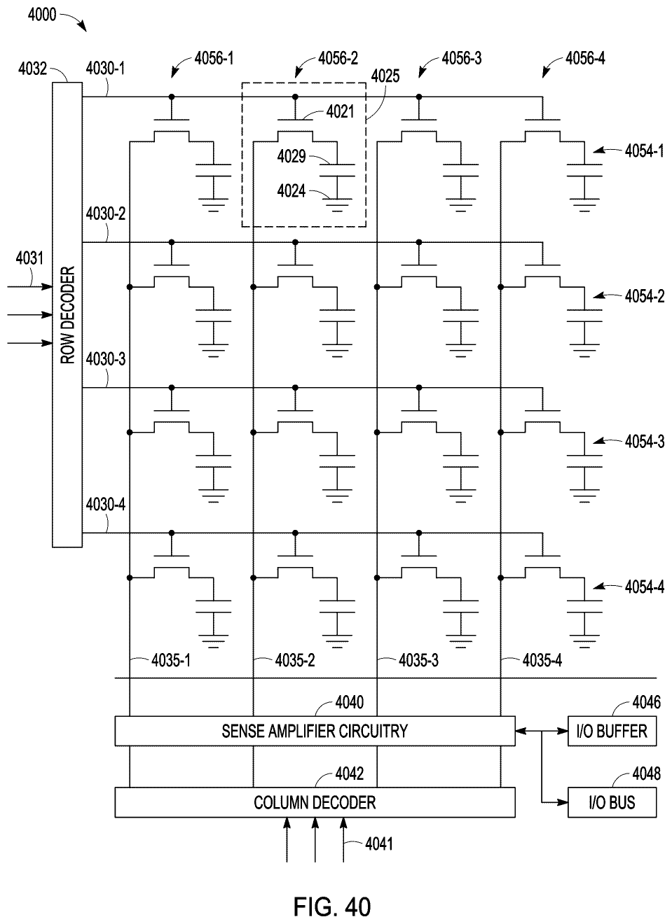

FIG. 40 is a schematic of an electrical arrangement of components of an embodiment of an example DRAM device 4000 that can include an physical architecture having an array of memory cells arranged as hexagonal cells, with each of the memory cells having a GAA transistor coupled to a capacitor. The memory cells can be coupled to BLs, where each of the BLs are separated from an adjacent BL by an airgap. Each WL can be structured contacting gates of GAA transistors of memory cells to which the given WL is coupled. The array of memory cells can be structured in an arrangement associated herein with respect to FIGS. 1-39. DRAM device 4000 can include an array of memory cells 4025 (only one being labeled in FIG. 40 for ease of presentation) arranged in rows 4054-1, 4054-2, 4054-3, and 4054-4 and columns 4056-1, 4056-2, 4056-3, and 4056-4. The physical orientation of the rows and columns is not limited to the orientation shown in FIG. 40. Further, while only four rows 4054-1, 4054-2, 4054-3, and 4054-4 and four columns 4056-1, 4056-2, 4056-3, and 4056-4 of four memory cells are illustrated, DRAM devices, like DRAM device 4000, can have significantly more memory cells 4025 (for example, tens, hundreds, or thousands of memory cells) per row or per column.

In this example, each memory cell 4025 can include a single transistor 4021 and a single capacitor 4029, which is commonly referred to as a 1T1C (one-transistor-one capacitor cell). One plate of capacitor 4029, which can be termed the “node plate,” is connected to the drain terminal of transistor 4021, whereas the other plate of the capacitor 4029 is connected to ground 4024 or other reference node. Each capacitor 4029 of memory cell 4025 within the array of 1T1C memory cells typically serves to store one bit of data, and the respective transistor 4021 serves as an access device to write to or read from storage capacitor 4029. Each transistor 4021 can be realized by a GAA nanowire transistor, as discussed with respect to FIGS. 1-39.

The transistor gate terminals within each row of rows 4054-1, 4054-2, 4054-3, and 4054-4 can be portions of respective WLs 4030-1, 4030-2, 4030-3, and 4030-4, and the transistor source terminals within each of columns 4056-1, 4056-2, 4056-3, and 4056-4 can be electrically connected to respective BLs 4035-1, 4035-2, 4035-3, and 4035-4. A row decoder 4032 can selectively drive the individual WLs 4030-1, 4030-2, 4030-3, and 4030-4, responsive to row address signals 4031 input to row decoder 4032. Driving a given WL at a high voltage causes the access transistors within the respective row to conduct, thereby connecting the storage capacitors within the row to the respective BLs, such that charge can be transferred between the BLs and the storage capacitors for read or write operations. Both read and write operations can be performed via SA circuitry 4040, which can transfer bit values between memory cells 4025 of the selected row of the rows 4054-1, 4054-2, 4054-3, and 4054-4 and input/output buffers 4046 (for write/read operations) or external input/output data buses 4048.

A column decoder 4042 responsive to column address signals 4041 can select which of the memory cells 4025 within the selected row is read out or written to. Alternatively, for read operations, the storage capacitors 4029 within the selected row can be read out simultaneously and latched, and the column decoder 4042 can then select which latch bits to connect to the output data bus 4048. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 4000 can be implemented as an IC within a package that includes pins for receiving supply voltages (for example, to provide the source and gate voltages for the transistors 4021) and signals (including data, address, and control signals). FIG. 40 depicts DRAM device 4000 in simplified form to illustrate basic structural components relative to electrical interactions, omitting many details of the memory cells 4025 and associated WLs 4030-1, 4030-2, 4030-3, and 4030-4 and BLs 4035-1, 4035-2, 4035-3, and 4035-4 as well as the peripheral circuitry. For example, in addition to the row decoder 4032, column decoder 4042, SA circuitry 4040, and buffers 4046, DRAM device 4000 can include further peripheral circuitry, such as a memory control unit that controls the memory operations based on control signals (provided, for example, by an external processor), additional input/output circuitry, or other features associated with a memory device. Details of such peripheral circuitry are generally known to those of ordinary skill in the art and not further discussed herein. The peripheral circuitry can be located above the array of memory cells 4025 in a CoA architecture using a wafer-to-wafer interconnect architecture. Alternatively, the peripheral circuitry can be located under the array of memory cells 4025 in a CuA architecture. Alternatively, the peripheral circuitry can be located in a region of the IC of the memory device adjacent an array region having the array of memory cells 4025.

In two-dimensional (2D) DRAM arrays, the rows 4054-1, 4054-2, 4054-3, and 4054-4 and columns 4056-1, 4056-2, 4056-3, and 4056-4 of memory cells 4025 can be arranged along a single horizontal plane (i.e., a plane parallel to the layers) of the semiconductor substrate, for example, in a rectangular lattice with WLs 4030-1, 4030-2, 4030-3, and 4030-4 and BLs 4035-1, 4035-2, 4035-3, and 4035-4. In 3D DRAM arrays, the memory cells 4025 can be arranged in a 3D lattice with a set of memory cells and associated WLs and BLs at a level above another set of memory cells and their associated WLs and BLs.

Memory devices having identical or similar features to example DRAM device 4000 and the structures associated with FIGS. 1-40 can be implemented in a variety of electronic devices. Electronic devices, such as mobile electronic devices (for example, smart phones, tablets, and other similar communication-related devices), electronic devices for use in automotive applications (for example, automotive sensors, control units, driver-assistance systems, passenger safety systems, comfort systems, or other similar systems), and internet-connected appliances or devices (for example, internet-of-things (IoT) devices, or other network-related devices), have varying storage needs depending on, among other things, the type of electronic device, use environment, performance expectations, or other criteria.

Such electronic devices can be broken down into several main components: a processor (for example, a central processing unit (CPU) or other main processor); memory (for example, one or more volatile or nonvolatile RAM memory device, such as DRAM, mobile or low-power double-data-rate synchronous DRAM (DDR SDRAM), or other similar memory devices); and a storage device (for example, non-volatile memory (NVM) device, such as flash memory, ROM, a solid-state drive (SSD), a MultiMediaCard (MMC), other memory card structure or assembly, or other similar storage devices). In certain examples, electronic devices can include a user interface (for example, a display, touchscreen, keyboard, one or more buttons, or other similar interfacing structure), a graphics processing unit (GPU), a power management circuit, a baseband processor, one or more transceiver circuits, or other similar device. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

The following examples are example embodiments of devices and methods, in accordance with the teachings herein.

An example memory device 1 can comprise: an array of memory cells arranged as hexagonal cells, with each of the memory cells having a GAA transistor coupled to a capacitor; WLs having a first WL coupled to gates of multiple GAA transistors of a first set of the memory cells; and BLs having a first BL coupled to multiple GAA transistors of a second set of the memory cells, each of the BLs being separated from an adjacent BL by an airgap.

An example memory device 2 can include features of example memory device 1 and can include each WL separated from an adjacent WL by a second airgap.

An example memory device 3 can include features of example memory device 2 and any of the preceding example memory devices and can include the multiple GAA transistors of the first set configured in a substantially linear arrangement and GAA transistors adjacent the multiple GAA transistors of the first set are not coupled to the first WL.

An example memory device 4 can include features of any of the preceding example memory devices and can include the multiple GAA transistors of the second set configured in a substantially linear arrangement and GAA transistors adjacent the multiple GAA transistors of the second set being not coupled to the first BL.

An example memory device 5 can include features of any of the preceding example memory devices and can include the first BL coupled to a first sense amplifier and a second BL, directly adjacent the first BL, coupled to a second sense amplifier.

An example memory device 6 can include features of example memory device 5 and any of the preceding example memory devices and can include the array of memory cells has an 8F² cell configuration.

An example memory device 7 can include features of any of the preceding example memory devices and can include the first BL is at least partially wrapped on a sidewall of an active area of each GAA transistor of the second set.

An example memory device 8 can include features of any of the preceding example memory devices and can include the memory device to include control logic and sensing circuitry above the array.

An example memory device 9 can include features of any of the preceding example memory devices and can include the control logic and sensing circuitry and the array of memory cells arranged in a wafer-to-wafer interconnect architecture.

An example memory device 10 can include features of any of the preceding example memory devices and can include a channel structure and active areas of the GAA transistor of a memory cell structured in a vertical nanowire.

In an example memory device 11, any of the memory devices of example memory devices 1 to 10 may include memory devices incorporated into an electronic apparatus further comprising a host processor and a communication bus extending between the host processor and the memory device.

In an example memory device 12, any of the memory devices of example memory devices 1 to 11 may be modified to include any structure presented in another of example memory device 1 to 11.

In an example memory device 13, any apparatus associated with the memory devices of example memory devices 1 to 12 may further include a machine-readable storage device configured to store instructions as a physical state, wherein the instructions may be used to perform one or more operations of the apparatus.

In an example memory device 14, any of the memory devices of example memory devices 1 to 13 may be formed in accordance with any of the below example methods 1 to 13 of forming a memory device.

An example method 1 of forming a memory device can comprise: forming an array of memory cells including forming the memory cells of the array as hexagonal cells and forming each of the memory cells having a GAA transistor coupled to a capacitor; forming WLs, with a first WL of the WLs coupled to gates of multiple GAA transistors of a first set of the memory cells; and forming BLs, with a first BL of the BLs coupled to multiple GAA transistors of a second set of the memory cells, each of the BLs being separated from an adjacent BL by an airgap.

An example method 2 of forming a memory device can include features of example method 1 of forming a memory device and can include forming vertical nanowires extending above a substrate, with the vertical nanowires having channel structures around which gates of the GAA transistors are formed.

An example method 3 of forming a memory device can include features of example method 2 of forming a memory device and any of the preceding example methods of forming a memory device and can include forming vertical nanowires to include forming epitaxial silicon on silicon germanium above a silicon substrate.

An example method 4 of forming a memory device can include features of any of the preceding example methods of forming a memory device and can include forming vertical semiconductor pillars for the GAA transistors, the vertical semiconductor pillars extending above a substrate; forming a dielectric between the vertical semiconductor pillars; patterning a damascene structure on the dielectric; forming metal, for the BLs of the set, wrapped at least partially on sidewalls of the vertical semiconductor pillar: forming a top dielectric covering the metal, pinching off top dielectric forming airgaps adjacent the BLs.

An example method 5 of forming a memory device can include features of example method 4 and any of the preceding example methods of forming a memory device and can include forming the top dielectric by forming a nitride using a PVD.

An example method 6 of forming a memory device can include features of example method 4 of forming a memory device and any of the preceding example methods of forming a memory device and can include forming a bonding dielectric on the top dielectric; attaching the bonding dielectric to a carrier wafer; arranging the carrier wafer as a bottom structure with the metal, covered by an isolation dielectric surrounding the vertical semiconductor pillars, arranged above the carrier wafer; and forming gate dielectrics and all-around gates for the GAA transistors above the isolation dielectric.

An example method 7 of forming a memory device can include features of example method 6 of forming a memory array and any of the preceding example methods of forming a memory device and can include forming the gate dielectrics by forming a high-k dielectric or forming an oxide by in-situ steam generation on the vertical semiconductor pillars.

In an example method 8 of forming a memory device, any of the example methods 1 to 7 of forming a memory device may be performed in forming an electronic apparatus further comprising a host processor and a communication bus extending between the host processor and the memory device.

In an example method 9 of forming a memory device, any of the example methods 1 to 8 of forming a memory device may be modified to include operations set forth in any other of example methods 1 to 8 of forming a memory device.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include forming features associated with any features of example memory devices 1 to 14.

An example method 12 of forming a memory device can comprise: preparing an array wafer with an array of GAA transistors connected to WLs and BLs, with the BLs separated from an adjacent BL by an airgap; preparing a control circuitry wafer; and coupling the array wafer and the control circuitry wafer together.

An example method 13 of forming a memory device can include features of example method 12 of forming a memory device and can include forming each WL separated from an adjacent WL by a second airgap.

An example method 14 of forming a memory device can include features of any of the preceding example methods 12-13 of forming a memory device and can include forming the array of GAA transistors as hexagonal memory cells in a 4F² architecture or an 8F² architecture.

In an example method 15 of forming a memory device, any of the example methods 12 to 14 of forming a memory device may be performed in forming an electronic apparatus further comprising a host processor and a communication bus extending between the host processor and the memory device.

In an example method 16 of forming a memory device, any of the example methods 12 to 15 of forming a memory device may be modified to include operations set forth in any other of example methods 12 to 15 of forming a memory device.

In an example method 17 of forming a memory device, any of the example methods 12 to 16 of forming a memory device may be implemented at least in part through use of instructions stored as a physical state in one or more machine-readable storage devices.

An example method 18 of forming a memory device can include features of any of the preceding example methods 12 to 17 of forming a memory device and can include forming features associated with any features of example memory devices 1 to 14.

An example machine-readable storage device storing instructions, which instructions, when executed by one or more processors, cause a machine to perform operations, can comprise instructions to perform functions associated with any features of example memory devices 1 to 14 or perform methods associated with any features of example methods 1 to 18 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells arranged as hexagonal cells, with each of the memory cells having a gate-all-around (GAA) transistor coupled to a capacitor;
access lines having a first access line coupled to gates of multiple GAA transistors of a first set of the memory cells; and
digit lines having a first digit line coupled to multiple GAA transistors of a second set of the memory cells, each of the digit lines being separated from an adjacent digit line by an airgap.

2. The memory device of claim 1, wherein each access line is separated from an adjacent access line by a second airgap.

3. The memory device of claim 1, wherein the multiple GAA transistors of the first set are configured in a substantially linear arrangement and GAA transistors adjacent the multiple GAA transistors of the first set are not coupled to the first access line.

4. The memory device of claim 1, wherein the multiple GAA transistors of the second set are configured in a substantially linear arrangement and GAA transistors adjacent the multiple GAA transistors of the second set are not coupled to the first digit line.

5. The memory device of claim 1, wherein the first digit line is coupled to a first sense amplifier and a second digit line, directly adjacent the first digit line, is coupled to a second sense amplifier.

6. The memory device of claim 1, wherein the array of memory cells has an 8F² cell configuration.

7. The memory device of claim 1, wherein the first digit line is at least partially wrapped on a sidewall of an active area of each GAA transistor of the second set.

8. The memory device of claim 1, wherein the memory device includes control logic and sensing circuitry above the array.

9. The memory device of claim 8, wherein the control logic and sensing circuitry and the array of memory cells are arranged in a wafer-to-wafer interconnect architecture.

10. The memory device of claim 1, wherein a channel structure and active areas of the GAA transistor of a memory cell are structured in a vertical nanowire.

11. A method of forming an memory device, the method comprising:
forming an array of memory cells including forming the memory cells of the array as hexagonal cells and forming each of the memory cells having a gate-all-around (GAA) transistor coupled to a capacitor;
forming access lines, with a first access line of the access lines coupled to gates of multiple GAA transistors of a first set of the memory cells;
and
forming digit lines, with a first digit line of the digit lines coupled to multiple GAA transistors of a second set of the memory cells, each of the digit lines being separated from an adjacent digit line by an airgap.

12. The method of claim 11, wherein the method includes forming vertical nanowires extending above a substrate, with the vertical nanowires having channel structures around which gates of the GAA transistors are formed.

13. The method of claim 12, wherein forming vertical nanowires includes forming epitaxial silicon on silicon germanium above a silicon substrate.

14. The method of claim 11, wherein the method includes:
forming vertical semiconductor pillars for the GAA transistors, the vertical semiconductor pillars extending above a substrate;
forming a dielectric between the vertical semiconductor pillars;
patterning a damascene structure on the dielectric;
forming metal, for the digit lines of the set, wrapped at least partially on sidewalls of the vertical semiconductor pillar; and
forming a top dielectric covering the metal, pinching off the top dielectric and forming airgaps adjacent the digit lines.

15. The method of claim 14, wherein the method includes forming the top dielectric by forming a nitride using a physical vapor deposition.

16. The method of claim 14, wherein the method includes:
forming a bonding dielectric on the top dielectric;
attaching the bonding dielectric to a carrier wafer;
arranging the carrier wafer as a bottom structure with the metal, covered by an isolation dielectric surrounding the vertical semiconductor pillars, arranged above the carrier wafer; and
forming gate dielectrics and all-around gates for the GAA transistors above the isolation dielectric.

17. The method of claim 16, wherein forming the gate dielectrics includes forming a high-k dielectric or forming an oxide by in-situ steam generation on the vertical semiconductor pillars.

18. A method of forming a memory device, the method comprising:
preparing an array wafer with an array of gate-all-around (GAA) transistors connected to access lines and digit lines, with the digit lines separated from an adjacent digit line by an airgap;
preparing a control circuitry wafer; and
coupling the array wafer and the control circuitry wafer together.

19. The method of claim 18, wherein the method include forming each access line separated from an adjacent access line by a second airgap.

20. The method of claim 18, wherein the method includes forming the array of GAA transistors as hexagonal memory cells in a 4F² architecture or an 8F² architecture.
